(19) United States
(12) Patent Application Publication
(10) Pub. No.: US 2015/0091255 A1
(43) Pub. Date: Apr. 2, 2015

(54) PISTON RING AND METHOD FOR THE PRODUCTION THEREOF

(71) Applicant: Wolfgang Issler, Schwaikheim (DE)

(72) Inventor: Wolfgang Issler, Schwaikheim (DE)

(73) Assignee: MAHLE INTERNATIONAL GMBH, Stuttgart (DE)

(21) Appl. No.: 14/376,922

(22) PCT Filed: May 16, 2012
(86) PCT No.: PCT/DE2012/000505

§ 371 Date: Dec. 10, 2014

(30) Foreign Application Priority Data
Feb. 8, 2012 (DE) 10 2012 002 447.9

(51) Int. Cl. F16J 9/12; C23C 14/04; C23C 14/58

(52) U.S. Cl. CPC F16J 9/12; C23C 14/588; C23C 14/046
USPC 277/442; 427/235

(57) ABSTRACT

A piston ring for pistons of internal combustion engines, comprising a ring running surface coated with a coating agent, a ring back, and two ring abutting ends spaced apart by a gap. In the region of at least one of the ring abutting ends, a groove running in the circumferential direction is provided in the ring running surface, the groove being filled up with the coating agent such as to be flush with the coated ring running surface.

The present invention relates to a piston ring for pistons of internal combustion engines, having a ring face coated with a coating agent, a ring back, and two ring joint ends spaced apart by means of a gap. The present invention furthermore relates to a method for the production of such a piston ring.

The ring face of a coated piston ring is subjected to increased wear during engine operation, particularly in the region of its ring joint ends. The cause for this is the reinforced contact of the ring joint ends with the cylinder wall. A known measure to counter this wear consists in increasing the thickness of the coating, at least in the region of the ring joint ends, but this leads to increased production and material costs.

The task of the present invention consists in further developing a piston ring of the stated type, that the wear in the region of the ring joint ends is at least reduced, in the simplest possible manner.

The solution consists in that a groove running in the circumferential direction is provided in the ring face in the region of at least one of the ring joint ends, which groove is filled with the coating agent, flush with the coated ring face.

The object of the invention is furthermore a method for the production of such a piston ring, in which an uncoated piston ring blank is provided with a groove running in the circumferential direction in the ring face in the region of at least one of the ring joint ends, and that subsequently, the ring face is coated with a coating agent, in such a manner that the groove is filled with the coating agent, flush with the coated ring face, and subsequently finish-machined.

According to the invention, it is therefore provided that the uncoated piston ring or piston ring blank is provided with a groove running in the circumferential direction, along its ring face, in the region of the ring joint ends. After subsequent coating of the ring face with the coating agent, this groove is completely filled with the coating agent. In general, final machining of the coated ring face takes place afterward. As a result, the layer thickness of the coating is reduced, but a greater layer thickness is maintained in the region of the groove than in the region of the remaining ring face. As a wear-resistant layer, the coating agent present in the groove is maintained as a reserve until contact with the cylinder working surface occurs here.

Advantageous further developments are evident from the dependent claims.

It is practical if the length of the groove amounts to two to ten times the axial height of the ring face, in order to reliably relieve stress on the regions of the ring face in the vicinity of the ring joint ends that is under particular stress. For the same reason, the depth of the groove should amount to 10 μm to 30 μm and/or the width of the groove should amount to 10% to 60% of the axial height of the ring face.

Depending on the requirements in an individual case, the groove can have a constant depth over its entire length, but it can also have a constantly decreasing depth, proceeding from the ring joint end, over its entire length. In comparable manner, the groove can have a constant width over its entire length, or a constantly decreasing width, proceeding from the ring joint end.

The thickness of the coating of the ring face typically amounts to 5 μm to 30 μm, preferably 20 μm. It is practical if the coating is configured as a PVD coating.

Exemplary embodiments of the present invention will be explained in greater detail below, using the attached drawings. These show, in a schematic representation, not true to scale:

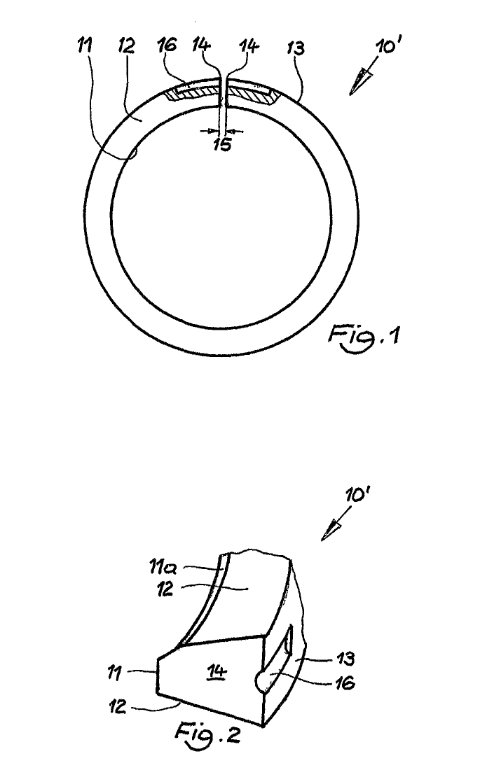

FIG. 1 a first exemplary embodiment of a blank for a piston ring according to the invention, in a top view, partially in section;

FIG. 2 a perspective detail view of the blank according to FIG. 1, in the region of a ring joint end;

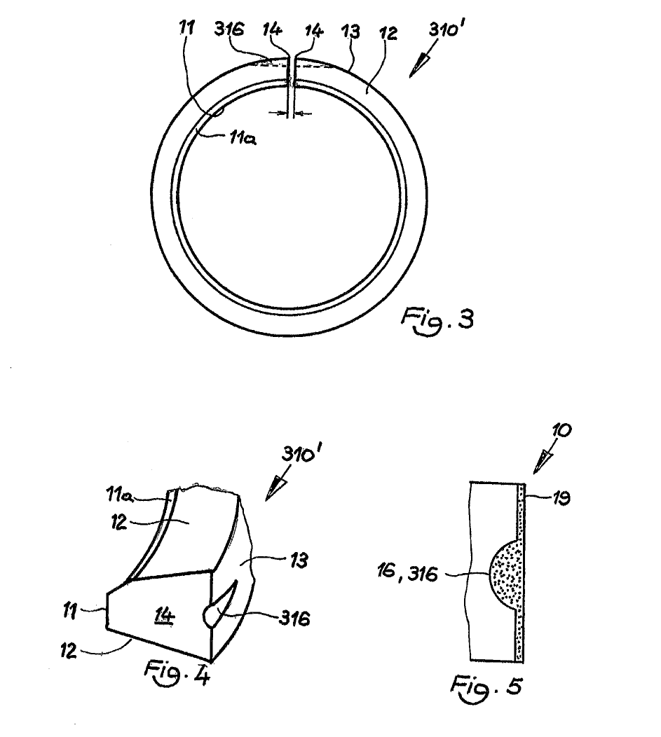

FIG. 3 a further exemplary embodiment of a blank for a piston ring according to the invention, in a top view;

FIG. 4 a perspective detail view of the blank according to FIG. 5, in the region of a ring joint end;

FIG. 5 a longitudinal section through the groove of a piston ring according to the invention, after coating and finish-machining of the ring face;

FIGS. 1 and 2 show a first exemplary embodiment of a blank 10′ for a piston ring 10 according to the invention. The blank 10′ has, in known manner, a ring back 11 provided with a bevel 11a, two ring sides 12, and a ring face 13. The blank 10′ furthermore has two free ring joint ends 14 that delimit a gap 15 or ring joint.

According to the invention, the blank 10′ has a groove 16 in its ring face 13, running in the circumference direction, in the region of each of the ring joint ends 14. The dimensions of the groove 16 depend on the dimensions of the blank 10′ and of the finished piston ring 10, and on the demands on the piston ring 10 during engine operation, and are at the discretion of the person skilled in the art. In the exemplary embodiment according to FIGS. 1 and 2, each groove 16 has a constant depth and a constant width. The length of the groove 16 generally amounts to two to ten times the axial height of the ring face 13. The depth of the groove generally amounts to 10 μm to 30 μm. The width of the groove 16 generally amounts to 10% to 60% of the axial height of the ring face 13.

The piston ring 10 according to the invention differs from the blank 10′ in that the ring face 13 has been coated with a coating agent, and the groove 16 has been completely filled with the coating agent, in other words flush with the coated ring face. For the sake of clarity, this coating agent is not shown in FIGS. 1 and 2.

FIGS. 3 and 4 show a further exemplary embodiment of a blank 310′ for a piston ring according to the invention. The blank 310′ essentially corresponds to the blank 10′ according to FIGS. 1 and 2, so that the same structural elements are provided with the same reference symbols, and reference is made to the description of FIGS. 1 and 2 in this regard.

The essential difference consists in that the blank 310′ has a groove 316 in its ring face 13, running in the circumference direction, in the region of each of the ring joint ends 14, which groove demonstrates a constantly decreasing depth and a constantly decreasing width, proceeding from the ring joint end 14. Of course, only the depth or only the width of the groove 316 can be configured to decrease constantly. The dimensions of the groove 316 depend on the dimensions of the blank 310′ and of the finished piston ring, and on the demands on the piston ring during engine operation, as was explained for the exemplary embodiment according to FIGS. 1 and 2. The number ranges stated there represent the leeway for the reduction in depth or width.

The piston ring according to the invention differs from the blank 310′ in that the ring face 13 has been coated with a coating agent, and the groove 316 has been completely filled with the coating agent, in other words flush with the coated ring face. For the sake of clarity, this coating agent is not shown in FIGS. 3 and 4.

FIG. 5 shows a piston ring 10 that can be obtained from a piston ring blank 10′, 310′ according to FIGS. 1, 2 and 3, 4, respectively. The piston ring 10 was coated with a coating agent 19 along its ring face 13, for example by means of a PVD method. As a result, the groove 16, 316 was filled with the coating agent 19. Subsequently, the coated ring face 13 was finish-machined in known manner. The thickness of the coating 19 on the face 13 of the finished piston ring 10 was 20 μm in the exemplary embodiment. In the end result, the groove 16, 316 is filled with the coating agent 19 up to the coated ring face 13, and the resulting coating has a greater layer thickness in the region of the groove 16, 316 than in the region of the remaining ring face 13.

1. Piston ring (10) for pistons of internal combustion engines, having a ring face (13) coated with a coating agent (19), a ring back (11), and two ring joint ends (14) spaced apart by means of a gap (15), wherein a groove (16, 316) running in the circumferential direction is provided in the ring face (13) in the region of at least one of the ring joint ends (14), which groove is filled with the coating agent (19), flush with the coated ring face (13).

2. Piston ring according to claim 1, wherein the surface of the coating agent (19) present in the filled groove (16, 316) is set back relative to the surface of the coating agent (19) present on the ring face (13).

3. Piston ring according to claim 1, wherein the length of the groove (16, 316) amounts to two to ten times the axial height of the ring face (13).

4. Piston ring according to claim 1, wherein the depth of the groove (16, 316) amounts to 10 μm to 30 μm.

5. Piston ring according to claim 1, wherein the groove (16) has a constant depth over its entire length.

6. Piston ring according to claim 1, wherein the groove (316) has a constantly decreasing depth over its entire length, proceeding from the ring joint end (14).

7. Piston ring according to claim 1, wherein the width of the groove (16, 316) amounts to 10% to 60% of the axial height of the ring face (13).

8. Piston ring according to claim 1, wherein the groove (16) has a constant width over its entire length.

9. Piston ring according to claim 1, wherein the groove (316) has a constantly decreasing width over its entire length, proceeding from the ring joint end (14).

10. Piston ring according to claim 1, wherein the thickness of the coating (19) on the ring face (13) amounts to 5 μm to 30 μm.

11. Piston ring according to claim 1, wherein the coating (19) is configured as a PVD coating.

12. Method for the production of a piston ring (10) for pistons of internal combustion engines, having a ring face (13) coated with a coating agent (19), a ring back (11), and two ring joint ends (14) spaced apart by means of a gap (15), wherein an uncoated piston ring blank (10′, 110′, 210′, 310′, 410′, 510′) is provided with a groove (16, 316) running in the circumferential direction in the ring face (13) in the region of at least one of the ring joint ends (14), wherein subsequently, the ring face (13) is coated with a coating agent (19), in such a manner that the groove (16, 316) is filled with the coating agent (19), flush with the coated ring face (13), and wherein subsequently the coated ring face (13) is finish-machined.
